(19) United States
(12) Patent Application Publication
(10) Pub. No.: US 2002/0094387 A1
(43) Pub. Date: Jul. 18, 2002

(54) Method for improving chemical vapor deposition of titanium

(76) Inventor: Mohan Krishnan Bhan, Cupertino, CA (US)

Correspondence Address: Patent Counsel, Legal Affairs Dept, Applied Materials Inc, PO Box 450A, Santa Clara, CA, 95052, US

(21) Appl. No.: 09/513,283

(22) Filed: Feb. 24, 2000

(51) Int. Cl. C23C 16/00

(52) U.S. Cl. 427/569; 427/251; 427/253; 427/248.1

(57) ABSTRACT

A method of conditioning a deposition chamber. The method comprises performing a pre-coat step and a plasma treatment step. The pre-coat step deposits a material layer upon interior surfaces of the chamber and its interior components, while the plasma treatment step further reduces the amount of undesirable residual gases.

### BACKGROUND OF THE DISCLOSURE

1. Field of the Invention

The invention relates to a method of processing a substrate in a deposition chamber and, more particularly, to a method of improving process and chamber performance for titanium deposition.

2. Description of the Background Art

In the manufacturing of very large scale integrated circuits (VLSI), titanium (Ti) is commonly used in conjunction with titanium nitride (TiN). The integrated Ti/TiN stack is often deposited upon a silicon substrate inside a contact hole or via prior to the deposition of a metal layer such as tungsten (W) or aluminum (Al). The Ti layer is used for contact silicidation to ensure low contact resistance. Among other things, the Ti layer also acts as a gettering material to absorb moisture, sodium (Na) and other impurities and as an adhesion layer, while TiN acts as a diffusion barrier between the silicon and the subsequently deposited metal.

Both Ti and TiN can be deposited using either physical vapor deposition (PVD) or chemical vapor deposition (CVD). In the case of CVD, for example, a multi-chamber system can be used to deposit the Ti and TiN layers sequentially in different chambers using thermal or plasma decomposition of a precursor gas such as titanium tetrachloride (TiCl₄). In the case of Ti deposition using TiCl₄, it is commonly known to use a chlorine (Cl₂) gas to clean the deposition chamber after each wafer deposition to ensure consistent chamber conditioning and thus improve wafer to wafer reproducibility.

There exists a need for a method of chamber conditioning to provide a Ti deposition process with improved process stability.

### SUMMARY OF THE INVENTION

Embodiments of the present invention provide, for example, a method of conditioning a chamber used for film deposition on a substrate. The method comprises generating a first plasma comprising titanium tetrachloride, followed by generating a second plasma comprising hydrogen inside the chamber.

### BRIEF DESCRIPTION OF THE DRAWINGS

The teachings of the present invention can be readily understood by considering the following detailed description in conjunction with the accompanying drawings, in which:

FIG. 1 schematically depicts a chamber suitable for practicing the present invention; and

FIG. 2 depicts a flow chart illustrating a process sequence incorporating chamber conditioning according to the present invention.

To facilitate understanding, identical reference numerals have been used, where possible, to designate identical elements that are common to the figures.

### DETAILED DESCRIPTION

The present invention can be practiced in any chamber used for Ti deposition from a TiCl₄ precursor gas. One example of such a chamber is the TECTRA™ CVD Ti chamber, which is one version of a TxZ™ chamber that has been adapted for Ti process applications. Both TECTRA™ CVD Ti and TxZ chambers are commercially available from Applied Materials, Inc., of Santa Clara, Calif. A brief description of the apparatus is provided below.

Apparatus

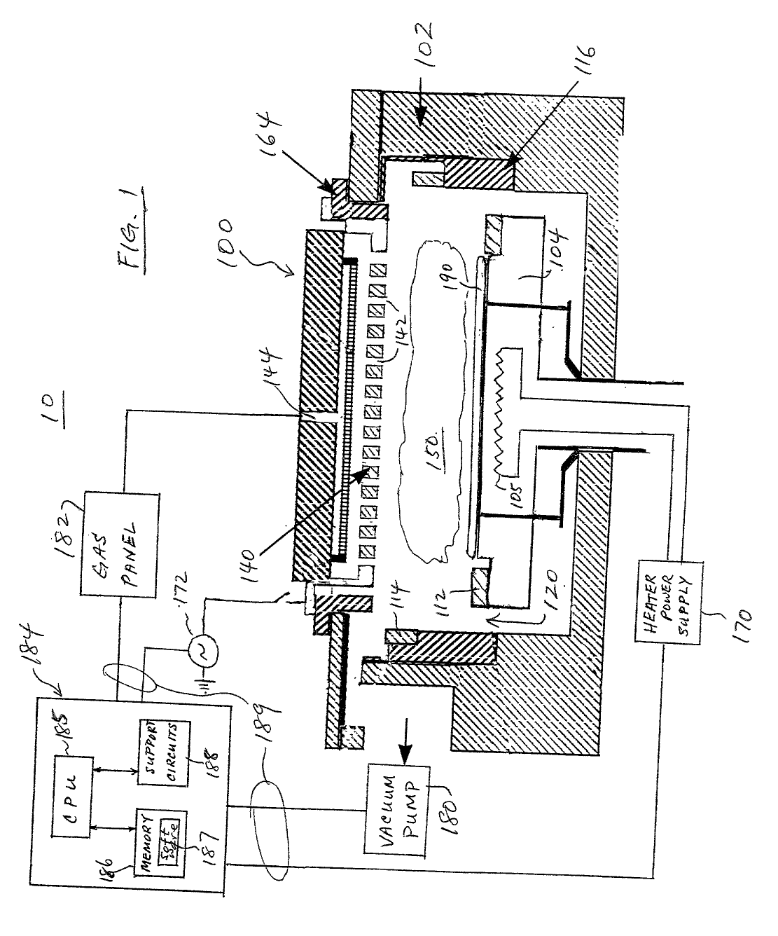

FIG. 1 is a schematic diagram illustrating an apparatus 10 comprising a CVD plasma reactor 100, such as a TECTRA™ CVD Ti chamber, that can be used for practicing the present invention. The TECTRA™ CVD Ti chamber 100 is configured for operation in a reduced pressure environment through connection to a vacuum pump 180, which is used to evacuate the process chamber 100 and to maintain the proper gas flows and pressure inside the chamber 100. The chamber 100 comprises a chamber body 102 and a pedestal 104 that supports a substrate 190 to be processed. Adaptations for the TECTRA™ CVD Ti chamber include, for example, a nickel-plated chamber body 102 and a ceramic heater pedestal 104. The substrate 190 is transferred in and out of the chamber 100 through a slit valve (not shown), and is placed upon the pedestal 104 by a transfer assembly. The pedestal 104 can typically be moved in a vertical direction inside the chamber 100 using a displacement mechanism (not shown).

During processing, the substrate 190 is placed below, and in close proximity to, a gas distribution faceplate, or a showerhead 140. The showerhead 140 is connected to a gas panel 182 which controls and supplies various gases used in different steps of a process recipe. The showerhead 140 comprises a larger number of passageways 142 which allow process gases from a gas inlet 144 to be uniformly distributed and introduced into a processing zone 150 inside the chamber 100. Proper control and regulation of the gas flows through the gas panel 182 is performed by mass flow controllers (not shown) and a control unit 184 such as a computer. Illustratively, the control unit 184 comprises a central processing unit (CPU) 185, support circuitry 188, and memories 186 containing associated control software 187. This control unit 184 is responsible for automated control of the numerous steps required for wafer processing—such as wafer transport, gas flow control, temperature control, chamber evacuation, and so on. Bi-directional communications between the control unit 184 and the various components of the apparatus 10 are handled through numerous signal cables collectively referred to as signal buses 189, some of which are illustrated in FIG. 1.

The CVD chamber 100 of FIG. 1 can be operated in two modes, thermal and plasma-enhanced. In the thermal mode, an electrical power source 170 supplies power to a resistive heater 105 within the pedestal 104. Other types of heaters, e.g., lamps, may also be used. The pedestal 104, and thus the substrate 190, are maintained at an elevated temperature sufficient to thermally activate the CVD reaction. A temperature sensor (not shown), such as a thermocouple, is also embedded in the wafer support pedestal 104 to monitor the temperature of the pedestal 104 in a conventional manner. The measured temperature may be used in a feedback loop to maintain the wafer temperature at a desired temperature which is suitable for the particular process application. Film deposition occurs on the surface of the substrate 190 when the process gas reacts at the heated substrate 190. Subsequently, most of the excess process gas and byproducts are pumped out of the chamber 100 by the vacuum pump 180.

In the plasma-enhanced mode, radio-frequency (RF) power from an RF source 172 is applied to the showerhead 140, which acts as an upper electrode. The showerhead 140 is electrically insulated from the rest of the chamber 100 by an annular isolator ring 164, typically made of an electrically non-conductive ceramic. Sufficient voltage and power is applied by the RF source 116 to generate a plasma from the process gases within the processing region 150. The chamber 100 is designed to minimize undesirable deposition upon various chamber components—e.g., an edge ring 112, is maintained at a lower temperature than the pedestal 104, such that film deposition on the edge ring 112 can be minimized.

Ti Deposition and Clean/Purge Process

The TECTRA™ CVD Ti chamber 100 can be used for CVD processes with different precursor gases, including titanium tetrahalides or metallo-organic precursors (e.g., tetrakis-(dialkylamino) titanium compounds). For Ti deposition using a titanium tetrahalide precursor, e.g., titanium tetrachloride (TiCl₄), an inert gas such as helium (He) is typically used as a carrier gas for TiCl₄ vapor. TiCl₄ is admitted into the chamber 100 through the showerhead 140, along with hydrogen (H₂). In one embodiment, argon (Ar) is also introduced into the chamber 100 through the showerhead 140, along with the other gases. The chamber pressure is maintained within a range of about 1 to about 20 torr, preferable about 5 torr, while the pedestal 104 maintains the substrate 190 at a temperature range of between about 550° C. to about 750° C., or preferably about 650° C. A plasma is then generated from the mixture containing TiCl₄, H₂, Ar and He, resulting in the deposition of a Ti layer upon the substrate 190. For example, TiCl₄ is supplied at a flow rate of about 50 mg/min., with a He carrier flow rate of about 2000 sccm, Ar flow rate of about 5000 sccm, and a H₂ flow rate of about 3000 sccm. An RF power of about 300 W is applied to the showerhead 140 to generate a deposition plasma. A purge flow using inert gases, e.g., argon (Ar), is also maintained at a flow rate of about 500 sccm to prevent undesirable deposition under the pedestal 104. In some Ti deposition applications, an increased TiCl₄ flow rate, e.g., about 150 mg/min. (or in general, greater than about 50 mg/min.) may be required. Note that the specific process parameters such as pressure, gas flow rates and RF power are exemplary values used in one embodiment of the invention—e.g., a TECTRA™ CVD Ti chamber for 200 mm wafers. In general, the invention can be practiced in other deposition chambers and process parameters may be modified as appropriate through experimentation.

When Ti deposition upon the wafer 190 is completed, the wafer 190 is removed from the chamber 100. Prior to the introduction of another wafer into the chamber 100, a clean/purge recipe is implemented whereby the interior of the chamber 100 and various components such as the showerhead 140, chamber shield 114, insert 116 and pedestal 104 are exposed to a cleaning gas. In a first step, a cleaning gas comprising chlorine—e.g., Cl₂, at a flow rate of about 100 to about 1000 sccm, preferably about 400 sccm, is admitted into the chamber 100 via the showerhead 140. This clean step, which preferably is performed for about 10 seconds, removes the residual Ti film from the interior of the chamber 100 and helps improve wafer-to-wafer reproducibility of the Ti deposition process and results in a low particle count. To avoid Cl₂ from flowing under the pedestal 104, an inert bottom purge gas flow (e.g., argon) in the range of about 100 to about 1000 sccm, preferably about 500 sccm, is also established. After the cleaning step, the chamber is purged by an inert gas, such as argon (Ar), at a total flow rate in a range of about 1000 to about 10000 sccm, and preferably, about 7000 sccm. In some applications, the chamber is ready for processing another wafer after the inert gas is pumped out of the chamber.

In other applications, however, especially those requiring an increased TiCl₄ flow rate, the chamber clean/purge procedure is modified according to the present invention, in order to improve the process reproducibility. The inventor has observed certain Ti deposition process instabilities—e.g., variations in the sheet resistance and uniformity of the deposited Ti films as well as high particulate contamination. These variations may occur from wafer to wafer within a single chamber or from chamber to chamber. The deposition variation problem becomes worse for certain applications—e.g., when the TiCl₄ flow rate is increased for depositing a thick Ti film at the bottom of a contact hole at an increased deposition rate. It is believed that this process instability is attributable largely to an effect of an increased TiCl₄ background, which may arise because a larger fraction of TiCl₄ will remain undissociated under high TiCl₄ flow rate and low RF power process conditions.

Embodiments of the invention seek to reduce the TiCl₄ background inside the chamber, as well as to improve chamber conditioning between subsequent Ti deposition on silicon substrates. Thus, the clean/purge procedure includes two additional steps after the conventional clean/purge sequence: 1) a “pre-coat” step in which a thin Ti layer is deposited upon interior surfaces of the chamber and its interior components; and 2) a hydrogen-containing plasma treatment step.

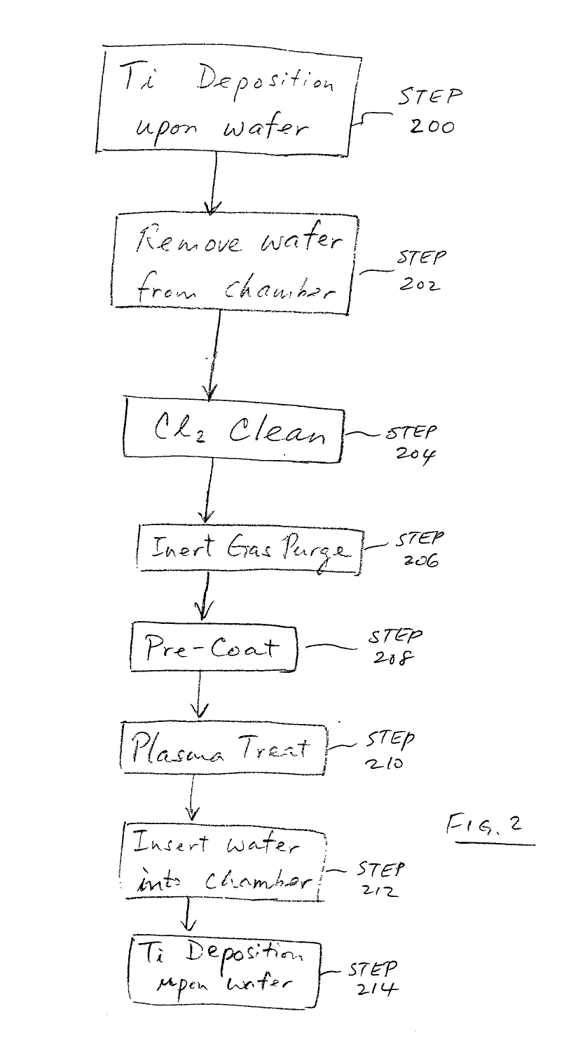

FIG. 2 is a flow chart illustrating several key steps in a wafer process sequence incorporating the present invention. The process steps may be performed in a deposition chamber such as that depicted in FIG. 1. During step 200, a Ti layer is deposited upon a wafer using a TiCl₄-based recipe. After the wafer is deposited with a Ti film, it is removed from the chamber in step 202. A clean step 204 is then performed in which the chamber is exposed to a chlorine-containing environment. For example, a chlorine gas (Cl₂) flow rate between about 100 to about 1000 sccm, or preferably about 400 sccm, is established for an appropriate time duration, e.g., about 10 sec. Depending upon the specific Ti deposition process, the duration of this purge step 204 may be adjusted as needed. Upon the completion of step 204, the chamber is purged by an inert gas in step 206.

According to the method of the present invention, a “pre-coat” step 208 is then performed using plasma-enhanced deposition, resulting in Ti deposition inside the chamber 100. The pedestal is preferably kept at the same temperature as used for the Ti deposition process (e.g., about 650° C). Typically, a TiCl₄ flow rate is established in a range of about 10 to about 100 mg/min., preferably about 50 mg/min. An inert gas flow—e.g., He at a flow rate of between 1000 to 5000 sccm, preferably about 2000 sccm, is used as a carrier gas for introducing TiCl₄ into the chamber 100. Other inert gases may also be used. A hydrogen (H₂) gas flow of between about 1000 to about 5000 sccm, preferably about 3000 sccm, is introduced into the chamber 100, and in one embodiment, an Ar flow rate of between about 2000 to about 7000 sccm, preferably about 5000 sccm, is also used along with TiCl₄ and H₂. A plasma is generated by applying an RF power in a range of about 100 to about 900 W, and preferably about 300 W. The RF power is usually applied to the showerhead 140. An inert purge gas flow of argon (Ar), for example, is also used to prevent undesirable deposition behind the pedestal 104. A total gas flow rate (e.g., He, H₂ and Ar) of between about 5000 to about 15000 sccm, preferably about 10500 sccm, is established. Other gases, especially inert gases, may also be used as carrier or purge gases, as long as they do not substantially interfere with the desired deposition chemistry.

During this pre-coat step 208, TiCl₄ is dissociated in the plasma, and a thin layer of Ti, e.g., in a range of about 10 to about 50 Å, is formed upon the interior surfaces of the chamber 100 as well as various components such as the showerhead 140, chamber shield 114 and insert 116. In one embodiment, the pre-coat step 208 is performed without any dummy substrate or wafer on the pedestal 104. As such, the pedestal 104 is also coated with a thin layer of Ti. Although the pedestal 104 exhibits a change in color, no noticeable adverse effects such as particulate contamination or changes in the Ti deposition process is observed as a result of the Ti coating on the pedestal 104. Alternatively, the pre-coat step 208 may also be performed with a dummy substrate placed on the pedestal 104 such that no Ti layer will be formed on the pedestal 104.

Different thicknesses of the pre-coat Ti layer can be achieved by varying the duration of the pre-coat step 208. For example, using the preferred deposition parameters, a 100 Å thick Ti film (measured by reference to a silicon oxide substrate) can be deposited in about 45 seconds. In one specific embodiment, a Ti film of about 30 Å is deposited inside the chamber 100 during about 15 sec. of this pre-coat step 208. This pre-coat step 208 conditions the interior the chamber 100 and its components, including the showerhead 140, chamber shield 114 and insert 116, and provides improved process stability without adverse effect on chamber performance. It is believed that a proper conditioning of the showerhead 140, in particular, plays an important role in providing a stable Ti deposition process. The TiCl₄ flow rate is selected, along with the deposition time, to ensure an adequate Ti coating upon the surfaces of the chamber 100 and various components.

Another aspect of the pre-coat step 208 seeks to minimize residual TiCl₄ or Cl₂ inside the chamber 100, because a high residual TiCl₄ or Cl₂ background is believed to contribute to process variations in the Ti deposition process. It is preferable that a TiCl₄ flow of about 10 to about 100 mg/min. be used for this pre-coat step, and preferably, about 50 mg/min. Similarly, a relatively high RF power, e.g., between about 100 to about 900 W, preferably about 300 W, is preferred because it results in a more complete dissociation of TiCl₄, and thus, a lower residual amount of TiCl₄ inside the chamber 100. In general, a high RF power will not only help break down TiCl₄ residue left during the deposition step and the Cl₂ clean step 204 (e.g., Cl₂ will convert the deposited Ti layer on the chamber interior to TiCl₄ gas by the reaction: Ti+2Cl₂→TiCl₄), but it also helps break down the additional TiCl₄ used for conditioning (pre-coating) the chamber 100. To characterize the process parameters for this pre-coat step 208, a ratio, r, can be defined by the TiCl₄ flow rate in mg/min. divided by the RF power in Watts. For example, for a TiCl₄ flow rate of about 50 mg/min. and an RF power of 300 W, the ratio r is equal to about 0.17. In general, a ratio of between about 0.1 to about 0.2 is acceptable. When the invention is practiced using other process chambers, adjustments of specific process parameters may be necessary, but a low TiCl₄ background is generally favored by maintaining a relatively low ratio r.

After this pre-coat step 208, the TiCl₄ flow into the chamber 100 is discontinued, and a plasma treatment step 210 is performed for a sufficiently long time, e.g., about 5 to about 30 sec., preferably about 10 sec., to further condition the chamber 100. The plasma in step 210 is generated by applying an RF power between about 100 to about 1000 W, preferably about 600 W, to the showerhead 140, with a gas comprising hydrogen (e.g., H₂) at a flow rate in the range of about 500 to about 2000 sccm, and preferably about 800 sccm. In another embodiment, a plasma comprising hydrogen and nitrogen is used. Such a plasma may, for example, comprise a mixture of H₂ and nitrogen gas (N₂), with a H₂ flow range of between about 100 to about 2000 sccm, and preferably about 800 sccm, along with a N₂ flow rate in the range of about 100 to about 2000 sccm, preferably about 800 sccm. The flow ratio of H₂:N₂ may range from about 0.05 to 20, and preferably about 1. In general, plasma treatment may also be accomplished by using other hydrogen-containing gases, singly or in combination with appropriate inert gases. The amount of residual Cl₂ and/or TiCl₄ inside the chamber 100 is further reduced after this plasma step 210.

Upon the completion of this plasma treatment step 210, another wafer is placed inside the chamber 100 in step 212, and Ti deposition is performed on the new wafer in the subsequent step 214. Using the method of the present invention, the Ti deposition process remains stable and shows excellent wafer to wafer repeatability of sheet resistance, resistivity and film uniformity for continuous processing of at least about 5000 wafers.

In general, the present invention can be practiced in conjunction with a variety of Ti deposition process recipes. However, the invention is particularly well-suited for use with a deposition recipe requiring a relatively high TiCl₄ flow rate and low RF power, which tends to result in a relatively high TiCl₄ background. Note that at a relatively high TiCl₄ flow rate and a low RF power, a considerable amount of TiCl₄ will remain undissociated inside the chamber, which will contribute to a high TiCl₄ background for the subsequent deposition. In addition, the Cl₂ clean step further adds to the high TiCl₄ background level by reacting with the deposited Ti film in the chamber interior, according to the following equation: Ti+2Cl₂→TiCl₄. Embodiments of the present invention are applicable in general to improve Ti deposition process stability, for example, by reducing the background levels of TiCl₄ or Cl₂ inside a deposition chamber.

Even though the present invention is disclosed for use with the TECTRA™ CVD Ti chamber, it can readily be adapted to other Ti deposition chambers. The specific process parameters such as gas flow rates, pressure, temperature and RF power and so on, are exemplary values for one embodiment using a TECTRA™ CVD Ti chamber designed for 200 mm wafers. Appropriate adjustments of these process parameters may be made for adaptations to other deposition chambers for practicing embodiments of the invention. Furthermore, the modified clean/purge recipe can be used in conjunction with Ti deposition at different stages of the integrated circuit fabrication sequence.

Although several preferred embodiments which incorporate the teachings of the present invention have been shown and described in detail, those skilled in the art can readily devise many other varied embodiments that still incorporate these teachings.

What is claimed is:

1. A method of conditioning a chamber for film deposition upon a substrate, comprising the steps of:
(a) generating a first plasma comprising titanium tetrachloride (TiCl₄) inside said chamber; and
(b) generating a second plasma comprising hydrogen inside said chamber.

2. The method of claim 1, wherein said chamber is used for depositing a film comprising titanium (Ti).

3. The method of claim 1, wherein said first plasma is a deposition plasma.

4. The method of claim 3, wherein said step (a) deposits a Ti layer inside said chamber.

5. The method of claim 1, wherein said steps (a) and (b) are performed with a dummy substrate inside said chamber.

6. The method of claim 1, wherein said steps (a) and (b) are performed without a dummy substrate inside said chamber.

7. The method of claim 1, wherein said first plasma is generated at a radio-frequency power of greater than about 100 Watts.

8. The method of claim 1, wherein said first plasma is generated at a TiCl₄ flow rate of less than about 100 mg/min.

9. The method of claim 1, wherein said first plasma is generated at a TiCl₄ flow rate and a radio-frequency power so that a ratio defined by said TiCl₄ flow rate in mg/min. divided by said RF power in Watts is between about 0.1 to about 0.2.

10. The method of claim 1, wherein said second plasma reduces chlorine and TiCl₄ from inside said chamber.

11. The method of claim 1, wherein said second plasma further comprises nitrogen.

12. The method of claim 11, wherein said step (b) is performed at a hydrogen to nitrogen ratio of between about 0.05 to about 20.

13. A processor readable storage medium, comprising a processor readable code having instructions that when executed by a processor causes a processing chamber for film deposition on a substrate to perform a method of chamber conditioning comprising the steps of:
(a) generating a first plasma comprising titanium tetrachloride (TiCl₄) inside said chamber; and
(b) generating a second plasma comprising hydrogen inside said chamber.

14. The processor readable storage medium of claim 13, wherein said processor readable code comprises instructions to deposit a Ti layer inside said chamber during said step (a).

15. The processor readable storage medium of claim 13, wherein said processor readable code comprises instructions to deposit a Ti layer inside said chamber from titanium tetrachloride (TiCl₄) during said step (a).

16. The processor readable storage medium of claim 15, wherein said processor readable code comprises instructions to generate said first plasma at a TiCl₄ flow rate and a radio-frequency power so that a ratio defined by said TiCl₄ flow rate in mg/min. divided by said radio-frequency power in Watts is between about 0.1 to about 0.2.
